(19) United States
(12) Patent Application Publication
(10) Pub. No.: US 2010/0315083 A1
(43) Pub. Date: Dec. 16, 2010

(54) Nuclear Magnetic Resonance Method for Quantitative and Qualitative Measurement of Natural Products

(75) Inventors: Guido F. Pauli, Chicago, IL (US); Birgit Jaki, Chicago, IL (US); David Lankin, Schaumburg, IL (US)

Correspondence Address: GREENLEE SULLIVAN P.C., 4875 PEARL EAST CIRCLE, SUITE 200, BOULDER, CO, 80301, US

(73) Assignee: The Board of Trustees of the University of Illinois, Urbana, IL (US)

(21) Appl. No.: 12/445,792

(22) PCT Filed: Oct. 19, 2007
(86) PCT No.: PCT/US2007/081969

§ 371 Date: Aug. 5, 2009

Related U.S. Application Data
(60) Provisional application No. 60/853,109, filed on Oct. 20, 2006.

(51) Int. Cl. G01R 33/48

(52) U.S. Cl. 324/309

(57) ABSTRACT

Provided herein are various methods and systems for analyzing natural products by quantitative proton nuclear magnetic resonance (qHNMR). A method is provided for quantitative and qualitative determination of a natural product by ¹HNMR and decoupling ¹³C nuclei from the protons in the sample containing the natural product. The resultant spectrum wherein the decoupling provides a cleaner spectrum is used to provide both structural and quantitative information about species within the sample. In an aspect, the decoupling is provided by globally optimized alternating-phase rectangular pulses (GARP). The methods presented herein are optionally used to detect impurities in a reference material and verify the purity level of a reference material.

### STATEMENT REGARDING FEDERALLY SPONSORED RESEARCH OR DEVELOPMENT

This invention was made with government support under P50-AT00155 awarded by NCCAM and ODS, and R21-A1052847-01 from NIAID/National Institute of Health. The government has certain rights in the invention.

### CROSS-REFERENCE TO RELATED APPLICATIONS

This application claims the benefit of U.S. Provisional Application No. 60/853,109, filed Oct. 20, 2007, which is incorporated by reference to the extent not inconsistent with the disclosure presented herein.

### BACKGROUND OF THE INVENTION

Natural products are important in a wide range of applications ranging from manufacturing processes for making pharmaceuticals, bioactive agents, chemical products, as well as for product development and testing, and as reference materials in a number of industries. The prevalence of natural products is a reflection that they are both well-defined chemical species and can have valuable biological activity in biological systems, as well as useful activity in non-biological systems. A difficulty with obtaining useful information about a natural product is that a natural product of interest is often found in a complex milieu of distinct species. Accordingly, tools are required to analyze natural products not only for quality control, but also to characterize a natural product of potential interest. One useful analytical tool is nuclear magnetic resonance (NMR), including proton NMR (HNMR).

HNMR is used extensively to provide structural information about a material as evidenced by the large number of patents and publications directed to HNMR. For example, HNMR and various HNMR schemes are presented in fields ranging from the wine industry (see Augustine et al. U.S. Pat. Pub. No. 2007/0001673) to biological materials such as carbohydrates (Lowman U.S. Pub. No. 2002/0142476), and for simultaneously measuring multiple samples (Raftery et al. U.S. Pat. No. 6,958,609). NMR is also used to analyze samples for the presence of controlled substances, such as methamphetamine and ephedrine, in samples that may range from pure drugs to mixtures containing any number of drug and nondrug additives. ¹H and ¹³C NMR permits relatively easy identification of cocaine and its derivatives. Appropriate quantitative HNMR (qHNMR) methods provide additional information related to quantification and profiling of natural product, natural product mixtures, and drug mixtures in general not available with other techniques. Quantitative HNMR is applied to a number of synthetic drugs in pharmaceutical preparations, such as bethanechol, furosemide, chlorpheniramine maleate, dicyclomine hydrochloride, propantheline, diphenhydramine hydrochloride, iopamidol and iothalamalate meglumine, azathioprine, and methocarbamol. qHNMR can be adapted for use in preparations from crude products/extracts through to final purified natural compounds and reference materials.

One difficulty, however, in using HNMR to analyze natural products is that natural products are generally rather complicated, and are often contained in a mixture of materials, resulting in a complex spectrum with a number of interfering peaks. Such spectra, with a large number of overlapping peaks are difficult to analyze, resulting in relatively insensitive spectroscopic methods. This presents difficulty for HNMR methods, and more particularly for quantitative HNMR (qHNMR) methods, where the amount of a natural product or other material in the mixture is sought. Quantitative NMR is a particularly attractive technique as it has the capacity to simultaneously provide qualitative and quantitative information about substances in a complex mixture, and uses are proposed in both discovery of new bioactive natural products and in the field of metabolome analysis.

A potential difficulty in working with natural products, is that unlike a synthesized product, a natural product typically must be separated from a complex mixture of chemically-related products. Structural information is, however, needed for both natural and synthetic materials for a number of reasons including quality control, purity analysis, and an understanding of the mode of biological activity. Such information is important for a number of reasons, such as permitting design of more potent and specific analogs or derivatives and reducing potential side effects by recognizing and, if appropriate, removing potentially harmful materials.

qHNMR is particularly useful in evaluating reference materials, as there is increasing regulation governing the various aspects of the pharmaceutical, environmental and manufacturing sectors. Such regulation is geared toward ensuring efficacy and safety of both the manufacturing process and the final product, whether it be a pharmaceutical, supplement or other material for ingestion, or another product which is marketed for human use. This increased concern toward validation of analytical and pharmacological reference standards makes qHNMR a potentially essential tool for analysis of these reference standards or materials. In contrast with traditional tools, such as chromatography, qHNMR is capable of being applied universally, is nondestructive, and provides precise and reliable results.

### SUMMARY OF THE INVENTION

Quantitative HNMR is capable of being applied universally, is nondestructive and provides precise and reliable results for a number of natural product applications, such as the identification and quantification (in a sequential or simultaneous manner), characterization, and discovery of bioactive natural products. A difficulty in the application of established methods for assaying natural products, such as conventional NMR and chromatographic-based methods, and for various related applications, is that it is extremely difficult to obtain useful and reliable quantitative information because of the relative complexity of the natural product and/or the matrix in which the natural product is situated. Such complexity leads to HNMR spectra having such a large number of peaks that practical quantification is unrealistic.

Standard techniques for providing and assessing purity, such as chromatographic purity, suffer from problems that HNMR avoids, such as co-elution and the need for standards to “calibrate” the chromatographic method (“response factors”). There is no such response factor in qHNMR, so that the qHNMR provided herein is considered a primary analytical method and produces signals directly proportional to the number of molecules in the sample (molarity) and are less prone to erroneous readings. Although certain chromatography-based methods may be more sensitive than qHNMR (e.g., LC mass spec. hyphenation), those methods always require standards to be quantitative and so can suffer from similar co-elution problems. This is an inherent problem in chromatographic methods, as chromatography is a separation-based system, whereas qHNMR is not. Because qHNMR does not require any standards for relative quantitation, and is a non-destructive analytical method, qHNMR disclosed herein is a significantly improved method for assessing the purity of natural product standards and is also capable of routine analysis of natural product mixtures, such as crude extracts and fractions. No other analytical method is capable of such universal applicability in such a straightforward manner. For example, the qHNMR methods presented herein are capable of being used for standardization of natural products (also known as “normation” when dealing with quantitation), as well as analysis of crude extracts and fractions.

An aspect of the present invention relates to qHNMR of a natural product with ¹³C decoupling to provide a ¹H spectrum with the ¹³C satellites collapsed, thereby providing a spectrum amenable to quantification. In addition, there is lack of peak overlap between ¹²C and ¹³C satellite peaks plus avoidance of any spinning artifacts that otherwise complicate the ¹H spectrum, thereby providing a relatively clean spectrum where nuisance peaks are reduced (e.g., compare the spectra from three different experimental conditions in FIG. 2). Accordingly, the technique is of universal applicability; it may be used in situations where there is a complex matrix of natural products within the sample, and can also be used in less complicated situations where there is one predominant natural product, and perhaps lower levels of impurities. In general, the nuisance or interfering peaks in classical routine ¹H NMR arise from relatively low abundance materials, resulting in severe problems for the materials present at less than about 10%. For this reason, users of HNMR generally do not examine materials present at that concentration level. The ability to measure and characterize (e.g., quantitative and qualitative determination) relatively low-level concentration materials, however, is a valuable and useful tool. The methods provided herein, in contrast, are useful in many applications ranging from quality control of materials to screens for identifying potentially useful natural products in a mixture of materials, to manufacturing processes related to chemical and pharmaceutical production.

In an embodiment, the invention is a method for qualitative and quantitative determination of a natural product by proton nuclear magnetic resonance. Natural product is used broadly to refer to, regardless of the source (e.g., plant, microbial, fungal, animal) an extract, fraction, and a relatively pure or isolated compound. In an aspect, any of the methods disclosed herein are used with a sample having one or more natural products that is an extract, fraction, or a relatively pure or isolated compound. In particular, a sample containing a natural product is provided and introduced into a measuring cell of a nuclear magnetic resonance analysis apparatus, such as an apparatus capable of providing a HNMR spectrum. In order to obtain a better quantifiable spectrum, the ¹³C nuclei in said sample is decoupled, such as by a composite pulse decoupling scheme. A spectrum is obtained wherein the decoupling removes or collapses the ¹³C satellites, so that the spectrum of the sample contains no significant ¹³C satellites. Accordingly the spectrum is capable of quantitative and qualitative determination. For example, the spectrum has peaks providing qualitative characterization of a species structure in the sample, and a shape parameter amenable to quantification by any means known in the art. For example, a post-processing means that determines peak height or calculates the area under the curve of the peaks, thereby providing quantitative determination of an amount of the species associated with the peak. To further provide spectra amenable to both qualitative and quantitative analysis or determination, one or more acquisition parameters are user-selectable, such as those parameters outlined herein and in Table 2. Of course, those parameters and the listed ranges, are not limiting or “fixed” parameters, but are presented as general guidelines and as a starting strategy to provide better spectra and sensitivity with the qHNMR methods disclosed herein.

In an aspect, the decoupling is provided by a Globally optimized Alternating-phase Rectangular Pulses (GARP) scheme. Any other method may be used, so long as the resultant spectrum is amenable to quantification. For example, Waltz-16, WURST, STUD are examples of decoupling schemes that may be used to provide adequate decoupling.

To further improve quantification, any of the methods optionally obtain a spectrum from a non-spinning sample.

In an embodiment, the natural product in the sample is a reference material, a biologically active material or precursor thereof, a mixture of one or more known natural products; or a mixture of one or more unknown natural products. Any of the natural products may be one or more of an extract, fraction or ranging up to a pure compound (e.g., isolated/purified compound).

In an aspect, the method relates to analyzing a reference material for one or more impurities. For example, the reference material can be a standard material, and to ensure adequate purity and structure, the material is analyzed by any of the methods of the present invention. This can be particularly useful for a reference material that is commercially sold for use in calibrating an analytical instrument. Any of the methods disclosed herein are particularly useful for a manufacturer of such material for quality control.

In another aspect, the method further provides for quantifying an impurity level, if present, and rejecting the reference material if the level of impurity exceeds a selected impurity level. Depending on the particular reference material, its intended use, and its desired grade, the impurity level can range significantly, such as a level that is selected from a range that is between, or better than, about 0.1% and 20%.

The method is optionally further characterized by any number of operating parameters, such as a dynamic range or minimum detectable impurity level. The methods provided herein are capable of functioning over any dynamic range, wherein the dynamic range may be selected depending on the particular application, sample composition (e.g., pure versus crude extract natural product) and desired sensitivity. In an embodiment, any of the methods disclosed herein are tailored to detect and/or characterize natural products present in a sample at a level less than 10%, less than about 1%, or any range therein, corresponding to a peak in the spectrum that is generally characterized as a “minor” peak. In an embodiment the dynamic range is relatively low, about 100:1; alternatively the dynamic range is relatively high (e.g., about 10,000:1), 400:1 or better, between about 350:1 to 250:1, or about 300:1, to facilitate detection of low level natural product or impurities. In another embodiment, the minimum detectable level of a species in the sample, such as an impurity, is as low as 0.005%, is about 0.1%, or between about 0.1% and 1%, for example. Of course, the particular value depends on a given NMR system and the application or sample composition. For example, even lower detection levels (e.g., less than 0.1%) are achievable with longer instrument time and/or with highly pure materials. As noted, the invention is compatible with any number of reference materials. In an embodiment the reference material is a mixture having a taxol, taxoid, or derivative thereof. Alternatively, the reference material is any one or more of a natural product belonging to biosynthetic compound classes including, but not limited to, phyenylpropanoids, acetogens, terpenoids, sugars and sugar derivatives, or amino acid-derived/alkaloidal natural products, or natural products of mixed biosynthetic origin, such as naturally occurring conjugates such as glycoside derivatives. Any compound at least partially produced by a biosynthetic pathway is encompassed by the term “natural product”.

In another embodiment, any of the methods are capable of quantitative and qualitative determination is from the same spectrum. This is referred to as “simultaneous determination.” Alternatively, the method may use different spectra depending on the desired information. In an aspect, any of the samples analyzed herein are capable of being used in subsequent tests, processes or manufacturing steps. In other words, any of the methods disclosed herein are non-destructive.

In an aspect, the invention provides improved sensitivity or selectivity (e.g., better peak resolution, product identification and/or quantification) by adjusting one or more NMR parameters disclosed herein. For example, by adjusting one or more of the parameters of Table 2. The parameter is optionally one or more of: spinning or non-spinning sample, shimming, composite-pulse decoupling scheme for broadband decoupling with minimum heat generation, wherein the decoupling scheme is GARP, WALTZ-16, WURST (Wideband, Uniform Rate, and Smooth Truncation) or STUD, pulse delay time, angle of pulse excitation, a spectral window, wherein a transmitter offset frequency for excitation of the desired spectrum is positioned in the center of the said spectral window, pulse width, acquisition times of between about 2 to 4 sec at about 400 MHz, Number of Scans or Transients, Receiver Gain Setting, number of steady-state pulses (between 1 and infinity, typically 2ⁿ, where n is between 0 and a large value, such as 1000); and ¹³C spectral window and a position of the ¹³C decoupler relative the ¹³C spectral window. The particular values can be empirically determined based on experimental conditions and sample composition, or can have any of the values disclosed herein.

Other embodiments of the invention relate to specific methods for detecting the presence or absence of an impurity in a sample by quantitative proton nuclear magnetic resonance spectroscopy. In this embodiment, in other words, the purity of a natural product or compound in a reference material is determined, and can be compared against a purity provided by the supplier, for example. In this aspect, the ¹³C decoupled spectrum provides the capability of quantitative and qualitative determination of the reference material and the capability of quantitative and qualitative determination of the impurity, if present. The qualitative determination provides a means for assigning a structure to an identified impurity. The quantitative determination provides a means for assigning an absolute or relative amount (e.g., percent by mass) impurity in said sample.

Any of the methods disclosed herein are optionally used with a natural product that is an active pharmaceutical ingredient.

Any of the methods disclosed herein are optionally used on a material or sample containing a natural product structure that is not known prior to performing said method.

The methods and systems disclosed herein are particularly suited for analysis of a complex mixture containing a plurality of natural products. Such a complex mixture can often pose significant challenges to conventional NMR spectroscopy. By providing decoupling of ¹³C nuclei in the mixture sample and obtaining a HNMR spectrum thereof, quantitative and qualitative determination of the complex mixture is possible, including of the plurality of natural products. In an aspect, the complex mixture may contain a specific natural product of interest, called a “target analyte”. In this aspect, the methods disclosed herein provide the capacity to assess a “quality control parameter” related to the target analyte. Examples of quality control parameter relates to the relative or total amount of the target analyte, analyte concentration, as well as amounts of other species and an indication of how structurally related the other species are to each other and the target analyte. Such a snapshot of the complex mixture optionally provides metabolomic information as to biochemical pathways in the manufacture of the target analyte by the system from which the mixture is obtained. Biological activity may also be assessed for those products that effect a detectable change in a measurable compound (e.g., an enzyme, compound that blocks enzymatic activity, or otherwise affects production of a compound).

### BRIEF DESCRIPTION OF THE DRAWINGS

FIG. 1. Inverse-gated decoupling scheme for eliminating the ¹³C satellites from ¹H NMR spectra, proposed as a routine experiment for acquisition of qHNMR data sets. The main building blocks of this experiment are the relaxation delay (a), the pulse width [pw] (b), the acquisition time (c), and the composite pulse decoupling GARP (d).

FIG. 2. Overview and expanded (A₁₋₃, B₁₋₃) plots of three representative qHNMR spectra [1-3] of a high-purity sample of taxol (6.3 mg in 600 μL CDCl_{3[}99.8% D], 5 mm probe, 400 MHz, ns=256): [1] qHNMR acquired under quantitative conditions (see text and Table 2) with spinning sample; [2] same as spectrum 1, but no spin; [3] same as spectrum 2, but with ¹³C broadband carbon decoupling using the GARP composite pulse scheme. The expansions are plotted at 100-fold vertical scale in order to visualize the rotation artifacts (R; rotation side bands) in spectrum 1, and the carbon satellites (*¹³C) in spectra 1 and 2. The latter are both absent in spectrum 3 (only the signal of the very minor impurity (i) is visible), which represents the proposed method for routine qHNMR. While region B is dominated by the large methyl resonances, example B3 demonstrates how GARP decoupling improves the impurity detection by eliminating satellites, e.g. in the δ1.35-1.55 region and from the minor impurity signals left isolated in B3 at δ2.05.

FIG. 3. For sufficient chemical shift dispersion, the qHNMR experiment can routinely detect and quantitate minor impurities with a good dynamic range (in this example 300:1 or better). This example demonstrates the relative intensities of the signals of the impurities i-2 (5.68%) and i-4 (0.25%) and their relationship with the main resonances of the 84.8% pure taxol sample B. The remarkable 400:1 dynamic range between taxol and its impurity i-4 also visualizes how readily the signals of minor impurities can be overlooked and/or buried under noise unless NMR spectra are acquired with adequate S/N.

FIG. 4 Vendor Implementation of the Acquisition of Routine GARP 13C-Decoupled qHNMR Spectra. A is a screenshot of a display when entering “edasp” for a Bruker NMR Spectrometer. B shows code for providing pulse sequence for decoupling during acquisition for a Bruker-Biospin NMR apparatus. C is code for a JEOL NMR Spectrometer (standard 1-D single pulse experiment); D is code for JEOL NMR Spectrometer with GARP decoupling during the acquisition; E is a JEOL NMR Spectrometer screen shot (1-D NMR). F is a JEOL NMR Spectrometer screen shot where the instrument is configured for GARP decoupling. G is a summary of a macro for routine GARP ¹³C-decoupled qHNMR on a Varian NMR Spectrometer.

FIG. 5 is a summary overview of experimental parameters (bottom) of interest that lead to quantitative conditions, with a number of applications.

### DETAILED DESCRIPTION OF THE INVENTION

The invention may be further understood by the following non-limiting examples. All references cited herein are hereby incorporated by reference to the extent not inconsistent with the disclosure herewith. Although the description herein contains many specificities, these should not be construed as limiting the scope of the invention but as merely providing illustrations of some of the presently preferred embodiments of the invention. For example, thus the scope of the invention should be determined by the appended claims and their equivalents, rather than by the examples given.

“Natural product” refers to naturally-occurring organic compounds such as a small molecule compound produced and/or isolated from a wide range of materials found in nature (e.g., soil, water, cells, plants, fungi, animals, bacteria, etc.). Small molecule refers to organic compounds having a relatively low molecular weight, such as less than 25000, 5000, 1000 or 500 Da. In an embodiment, the natural product or the target analyte has a molecular weight that is less than about 5000 Da. As used herein, natural product is used broadly to refer to a natural product ranging from a raw material or extract from a source organism, such as a mixture of natural products, to an isolated and substantially pure natural product. A natural product is biosynthesized by a biological organism, such as a naturally-occurring organism or a genetically engineered organism, and includes semi-synthetic modification and derivitization of such compounds. The natural product may have a terrestrial and/or marine source. Accordingly, natural product is also defined as a product made from a biosynthetic pathway. The main biosynthetic routes of natural products are the acetate/mevalonate pathway, the isoprene pathway, and the amino acid derivatives, for example. In addition, there are “mixed” biosynthetic products where two or three of these pathways are combined to make the compound. A sample may contain any level of natural product, wherein the natural product can range from a crude material, an extract, a fraction, or a material isolated therefrom.

The natural product may be present as a “complex mixture.” “Complex mixture” refers to a sample having more than one natural product, or a natural product having one or more impurities giving rise to a detectable HNMR peak. Alternatively, the natural product may be present as a high purity or medium purity material. “High purity” refers to a natural product having a purity that is greater than 90%, greater than 95%, or greater than 97%. “Medium purity” refers to a natural product having a purity that is selected from a range that is between about 50% and 90%. Alternatively, the natural product may be a crude extract. “Crude extract” refers to an impure form of an isolated natural product or compound, where in addition to the natural compound, other compounds are present, such as compounds involved in the biosynthetic pathway, or compounds derived from the source material. These extracts, when combined with the qHNMR techniques disclosed herein, may provide valuable metabolomic information, and thereby permit assessment of the source organism metabolic state and pathways related to the biosynthesis of the natural product.

“Qualitative determination” refers to structural-type information obtained from qHNMR spectra. As known the art, peaks in a spectrum obtained from HNMR correspond to specific residues in a structure. Accordingly, evaluating the position of the peaks in a spectrum provides structural information about the natural product or contaminants contained in the analyzed sample.

“Quantitative determination” refers to a parameter that can be quantified, such as concentration or amount of natural product or contaminant in a sample. In general, the information contained in the spectrum obtained by qHNMR provides both determinable quantitative and qualitative information. Quantitative determination refers to both relative and/or absolute determination, where a compound of interest may be determined relative to the amount of another compound, such as the major component in the sample, or is expressed in terms of percent by weight. In an aspect, the quantitative determination provides a measure of an amount of a substance (e.g., mass, concentration, or molarity). The difficulty with conventional qNMR, as applied to the natural product methods presented herein, is that the relatively complicated components within the sample generate spectra that are too complicated to provide a reliable quantitative measure. In contrast, the present invention provides, in an aspect, the capability of simultaneous qualitative and quantitative determination. Simultaneous refers to a single spectrum providing both qualitative and quantitative information for a sample containing one or more compounds including at least one natural product. As recognized in the art, one means for obtaining quantitative information from the spectra obtained from NMR spectroscopy involves postprocessing techniques, wherein the area or height of different peaks and/or spectrum portions are determined to provide a measure of the mass or concentration of the species associated with those peaks or portions.

In an aspect, a natural product, reference material, impurity or other compound of interest is quantified by analyzing one or more shape parameters of a peak or plurality of peaks within the spectrum. This quantification is optionally a post-processing technique known in the art, such as by measuring a peak height, width of the peak and/or an area under the peak or portion thereof. Comparing different peaks generates information about relative amounts of the materials associated with each of the peaks.

“Sample” refers broadly to the material that is introduced to the NMR apparatus. As used herein, sample contains at least one natural product for which the user desires qualitative and quantitative information. The sample can contain a mixture of natural products, or a natural product and any number of synthetic products. For example, the sample can be an extract or isolate of an organism, wherein structural and quantitative information is desired for one or more natural products. Alternatively, the sample is optionally an isolated and purified material or natural product, e.g., a pharmaceutically active material, where information is desired about the purity level of the material or natural product, and if there are any other material, information related to the structure and amount of the other material. Alternatively, the sample is a reference material or a reference standard, where the methods disclosed herein provide quality control information about the sample. In an aspect, the sample comprises a liquid material in which a natural product is suspended, such as a natural product that is a solid, liquid or gas.

“Measuring cell”, as known in the art, is the region of the NMR analysis apparatus that holds a sample and in which a magnetic field is applied and a corresponding signal measured.

“Decoupling” refers to application of a composite pulse scheme to suppress, reduce or eliminate ¹³C satellites from the ¹H spectrum, thereby providing a spectrum conducive for both qualitative and quantitative determination. Decoupling schemes known in the art include, but are not limited to, CW, WALTZ, GARP, and MPF7 modulation schemes, which are known to produce acceptable decoupling (see, e.g., U.S. Pat. No. 5,847,564). In an aspect, the decoupling is provide by a globally optimized alternating-phase rectangular pulses (GARP) scheme (see, e.g., Schoen et al. Int. J. Parasitol. 1996 26:713-722; Meusinger et al. Fuel 1996 75: 1235-1243 and Anal. Chim. Acta 1999 391:277-288; Shaka et al. J. Magn. Reson. 1985 64:547-552; Pauli J. Nat. Prod. 2005 68:133-149). Other example of broadband composite decoupling schemes include, but are not limited to, STUD (M. R. Bendall and T. E. Skinner. “Calibration of STUD decoupling to achieve selected sideband amplitudes.” J. Magn. Reson., A120, 77-87 (1996)), WALTZ, WURST (Kupce, E., Freeman, R. Adiabatic pulses for wideband inversion and broadband decoupling A 115 273-276. J. Magn. Reson.), for example. Those of ordinary skill in the art will recognize, however, that any related composite pulse decoupling scheme may be used to collapse ¹³C satellites from the ¹H spectrum.

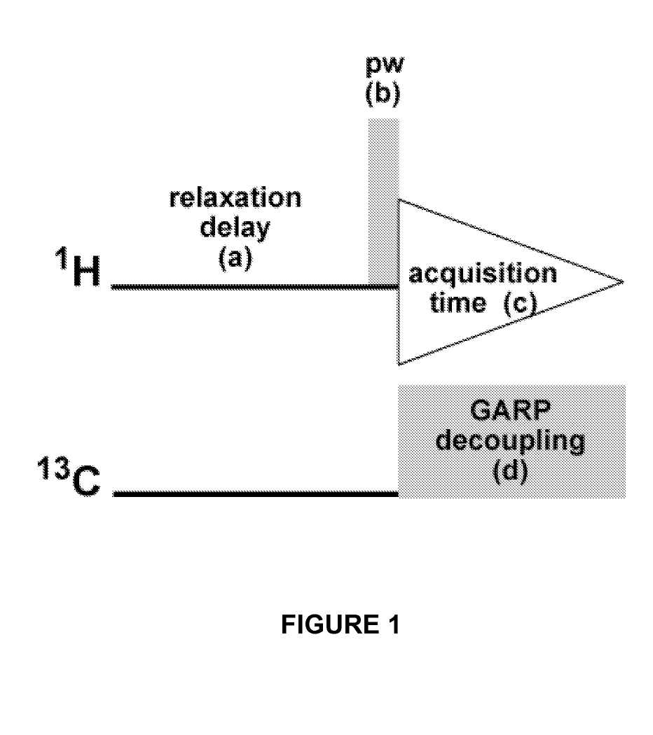

As understood by those of ordinary skill in the art, any method that provides heteronuclear decoupling at the radio frequency of the ¹³C nuclei to collapse the ¹³C satellites may be used. The ¹³C isotope is present to the extent of 1.1% in the sample. Because it is a spin ½ nucleus, it will couple to the proton resonances, producing satellites at 0.55% integrated intensity that flank the principal proton resonance bound to ¹²C (spin) 0). The separation between the centers of the satellites is the one-bond (1JH,C, typically 100-200 Hz) coupling constant. These satellite resonances can overlap with other signals of the primary analyte or with signals arising from impurities present in the sample. By irradiating at the center of the carbon frequency range (ca. 100-110 ppm) during the acquisition (aq) period of a proton NMR experiment (FIG. 1), the result will be a ¹H NMR spectrum with the ¹³C satellites collapsed. It then becomes a simple task of integrating the proton spectrum for assessing the quantitative composition of the sample. This represents an excellent general protocol for obtaining qHNMR spectra of samples that are mixtures of, for example, natural products.

Several caveats to the decoupling step should be mentioned. First, a composite pulse-decoupling scheme is used for the experiment to reduce, in part, sample heating. The use of continuous decoupling, because of the power levels necessary to fully decouple ¹³C, is not viable since it can potentially cause damage to the probe. In addition, sample heating can be extensive and may run the risk of decomposing the sample. The Waltz-16 composite pulse-decoupling scheme (Simeral Appl. Spectrosc. 1995 49:400-402) can be used, but a better scheme using GARP decoupling (globally optimized alternating-phase rectangular pulses) (J. Magn. Reson. 1985 64: 547-552) may be employed. GARP provides more efficient decoupling over the wider spectral window associated with the chemical shift range (ca. 220 ppm) of the ¹³C spectral region and should be used especially on higher field instruments with proton observation frequencies of 400 MHz or greater. Decoupling should be performed only during the acquisition (aq) of the FID (inverse gated decoupling), again to reduce the problem of sample heating. To reduce concerns associated with the possible buildup of NOE during an inverse-gated decoupled qHNMR experiment, one option is to shorten the acquisition time and regain the sacrificed spectral and digital resolution by zero-filling. Selection of the d1 delay should also be judicious in this regard. If d1 is too short, this will increase the percentage of time that the decoupler remains on (decoupler duty cycle) and lead to an increase in sample heating. So, while a suitable repetition rate (d1+aq) may have been optimized to yield quantitative conditions, additional care should be taken with respect to the selection of the length of the d1 delay to minimize sample-heating effects. Decoupling is further discussed in Example 1 below.

“Dynamic range” refers to the smallest detectable level of a compound or peak relative to the largest level of detected compound or peak. For example, a dynamic range of 300:1 refers to the system having the capacity to detect an impurity at the level of 0.3% compared to the dominant species in the spectrum. In an aspect, dynamic range does not refer to the absolute largest peak (which could correspond to, for example, a solvent signal such as water), but instead refers to the highest “true analyte peak” such as the main compound in a pure reference standard.

“Reference material” refers to a specific class of samples, such as commercially supplied materials that are useful in calibrating various analytical apparatuses. In particular, a reference material generally is supplied with information regarding the purity level and chemical structure of the compound. The methods provided herein are particularly suited for analyzing reference materials for validation of purity level and structural information as to potential contaminants. “Characterizing”, such as characterizing an impurity, is used herein to refer to quantitative, qualitative or both quantitatively and qualitatively analyzing a substance within the sample, such as an impurity.

As used herein, “known” refers to a natural product, such as an isolated and purified natural product used in pharmaceuticals, having a well-characterized structure. In contrast, “unknown” refers to a natural product that is not well-characterized in that there is uncertainty as to the structure or the assignment/interpretation of spectroscopic data. This is common in natural products of potential use as a bioactive agent, and particularly to identify natural products identified within a mixture of compounds, where the mixture demonstrates efficacy when screened for activity.

“Impurity” refers to an unwanted species contained within the reference material. Such impurities are useful to detect and characterize in that they may interfere with instrument calibration, or whose presence is unwanted when a “pure” material is desired in chemical or pharmaceutical manufacturing, for example, or in the fine chemical industry. Levels of a substance given in percent, refers to the percent by weight of the substance.

“Non-destructive” refers to methods wherein the sample that is tested is not adversely affected by the test, such that the sample may be used in subsequent tests, assays, manufacturing processes, or the like.

“NMR parameter” refers to one or more controllable settings associated with the qHNMR method which can be user-selectably adjustable to improve signal to noise, resolution, sensitivity or the like. This parameter is optionally selected based on the natural product of interest and the conditions in which the natural product is detected (e.g., extracts versus purified isolates). Any one or more of the parameters listed in Table 2, for example, is an NMR parameter. “Solvent suppression” refers to techniques known in the art that can further reduce unwanted peaks generated by the solvent, and provide “cleaner” HNMR spectra and increase the dynamic range of a given experiment.

### Example 1

### qHNMR Operating Parameters

Quantitative ¹H NMR (qHNMR) provides a value-added dimension to the standard spectroscopic data set involved in structure analysis, especially when analyzing bioactive molecules and elucidating new natural products. The qHNMR method can be integrated into any routine qualitative workflow without much additional effort by simply establishing quantitative conditions for the standard solution ¹H NMR experiments. Moreover, examination of different chemical lots of taxol and a Taxus brevifolia extract as working examples provides a blueprint for a generic approach to performing a routinely practiced ¹³C-decoupled qHNMR experiment, and for recognizing its potential and main limitations. The protocol is based on a newly assembled ¹³C GARP broadband decoupled proton acquisition sequence that reduces spectroscopic complexity by removal of carbon satellites. The method is capable of providing qualitative and quantitative NMR data simultaneously and covers various analytes from pure compounds to complex mixtures such as metabolomes. Due to a routinely achievable dynamic range of 300:1 (0.3%) or better, qHNMR qualifies for applications ranging from reference standards to biologically active compounds to metabolome analysis. The methods outlined herein provide a map for using qHNMR to analyze any natural product in any number of conditions, ranging from a crude extract or isolate to a final isolated and purified end product. Acquisition conditions are described that can be adapted for contemporary NMR spectrometers of all major manufacturers, thereby providing a readily configurable system for qualitative and quantitative determination of a natural product, including a natural product in a complex biological matrix of materials.

The world's pool of natural products plays an important role as an (in)exhaustible resource for evolutionary-shaped molecules. Natural products are valuable research tools, which in part is due to their biological potency (see comprehensive reviews¹⁻⁴). When natural products are used as biomedical agents, and in consistency with the pharmacophore model, it is the combination of their specific chemical structure and/or reactivity that forms their relationship with a biological target and ultimately defines their essential structural features. Consequently, chemical constitution plays a key role in biological activity, and, therefore, all structure related information obtainable from a biologically active agent is by default relevant. Ultimately, any variation of structural parameters has the potential to introduce variations in biological activity. This relationship holds regardless of the magnitude of the biological perturbation, i.e., whether there is slight or a substantial change in potency, or even an alteration in the type of biological response. The well-documented subtleties of mammalian hormonal steroids can serve as a distinguished example in this regard.

Typically, the relationship between chemical structure and biological activity is explored through semi-empirical systematic, structural alterations by performing (semi)synthetic variation or investigation of families of closely related structures such as natural isolates or synthetic derivatives. In the case of natural products, and in the context of the chemistry-biology interface, it is equally important to recognize that the chemical composition of natural or synthetic bioactive agents may not necessarily be represented by a single chemical entity (SCE). Instead, the composition might be rather complex and involve a mixture of chemical entities. As a consequence, biological activity, efficacy and off-target side effects becomes closely related to the purity of isolates and/or the impurity profiles of major constituents, isolates, and reference materials.

By virtue of both its comprehensive qualitative (δ, J, nOe, T₁, T₂; see ⁵ and references therein) and quantitative capabilities,⁵ nuclear magnetic resonance methodology (NMR and qNMR, respectively) can contribute in multiple ways to the aforementioned biology-chemistry relationship. Moreover, the combination of NMR and qNMR can act synergistically by supplying in a concurrent manner valuable structural (e.g., “qualitative”) and quantitative information about nature's “small” molecules that are involved in biological action by providing the following: (i) confirmation of chemical structure and structure-activity relationships; (ii) insight into structural equilibria (e.g., tautomerism or pH-dependent species formation); (iii) purity determination of bioactive agents and/or determination of impurities, which might interfere with the bioassay; (iv) exploration of the structural analogues contained in complex matrices (“biosynthetic cocktails”) and the metabolomic composition of mixtures.

Because natural products, at least initially, have to be purified from complex matrices, their chromatographic purification and structural analysis are relatively complicated. It should be kept in mind that through chemical shift (δ) dispersion, NMR also has intrinsic differentiation capability and can resolve nuclei of the same molecule from nuclei of other molecular species contained in the same sample. Significant additions to the “separation” power of NMR arise from its capability to create multi-dimensional (nD) dispersion via spin-spin (J) or dipolar (D) coupling, heteronuclear chemical shifts (δ_{X}), and/or diffusion (D). While nD qNMR development is ongoing, the 1D qNMR method already allows a powerful discrimination of multi-component mixtures or impurities in isolates. In particular the 1D ¹H variant of qNMR, qHNMR, adds a combined quantitative-qualitative dimension to the structural NMR portfolio of any natural product, and has the potential to make a fundamental contribution to the bigger picture of structure-activity correlations.

Considering the above, and in the context of more than 100 reports on the use of quantitative NMR in natural products and related sciences, mainly pharmaceutical, food and drug analyses,^{5,6} there is a significant potential for a standardized qHNMR method, i.e., a method that can be applied in routine purity analysis and quantitation of complex mixtures.⁷ Of interest is that generally the art does not address or characterize substances corresponding to “minor peaks”, such as a peak corresponding to a 1% level or below of a natural product. Accordingly, there is a lack of studies using ¹³C decoupling to provide quantitative and qualitative determination of natural products by HNMR spectra analysis. Studies using the qHNMR methods disclosed herein indicate that the minor peaks that are typically ignored in conventional methods often correspond to impurity levels that are 10% or more.

Choice of Taxol as qHNMR Model Sample: While qNMR analyses is applicable to a variety of natural products and synthetic or semi-synthetic compounds, taxol is selected as a representative sample to develop the qHNMR protocol for the following reasons: (i) taxol provides a rather complex ¹H NMR spectrum, covering almost the entire ¹H chemical shift range that is typically of interest; (ii) taxol represents a key example of a natural product with both interesting biological activity and structural novelty; (iii) the NMR spectroscopic assignments have been previously reported and its conformational dynamics in solution have been elucidated, making taxol a well-documented molecule; (iv) because of the known solution dynamics associated with taxol, in which Z/E isomerism about an amide linkage are readily observable at room temperature, additional challenges are presented for implementation of the qHNMR approach. It is understood, however, that the methods and systems presented herein are not limited to taxol, but are useful in assessing a wide range of samples and sample mixtures containing one or more natural products.

In order to demonstrate the suitability of the qHNMR method for routine analysis, the study is designed to require the minimal amount of structural information on the impurities. Therefore, instead of relying on involved studies required to clarify the precise nature of the most abundant taxoid analogues/impurities present in each sample, the impurities are compounded into the calculation under the assumption of having equal or at least similar molecular weights. Because a complete molar mass balance is not achievable, the 100% model is employed, representing a method typically used in chromatographic impurity profiling where response factors are also often unknown. Finally, the samples are analyzed in a blinded fashion, and without prior knowledge of LC-based impurity profiles.

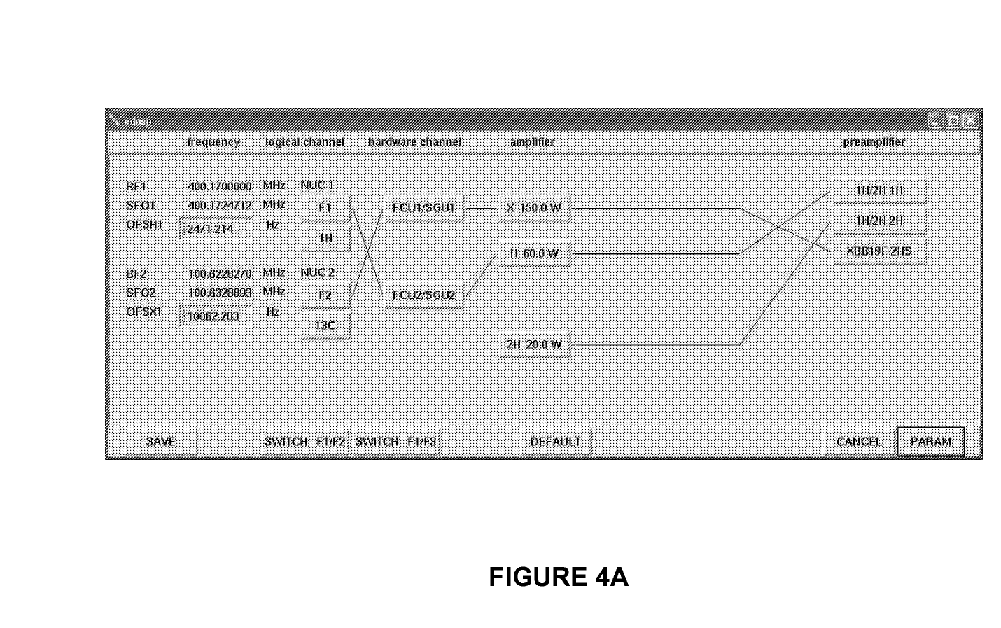

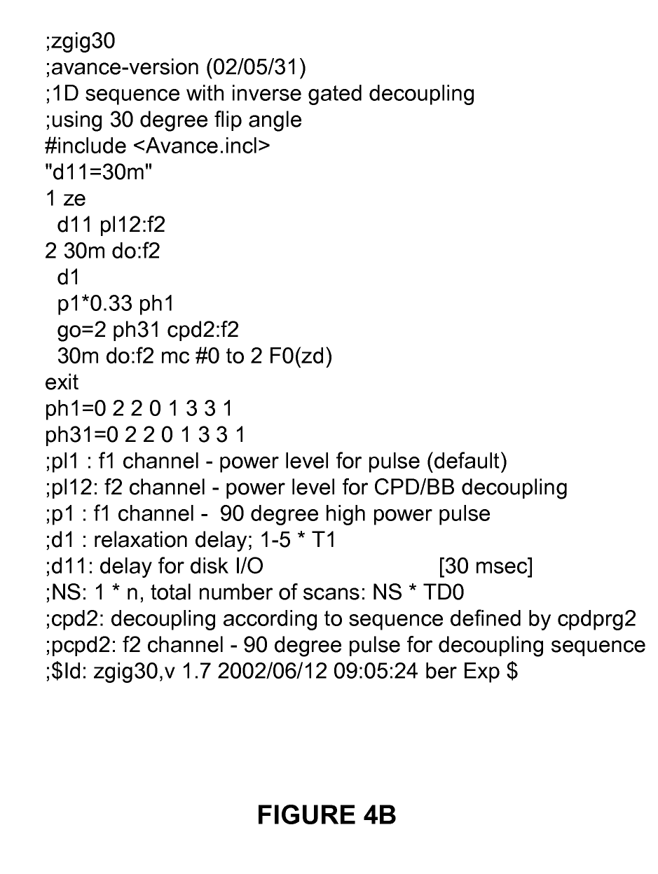

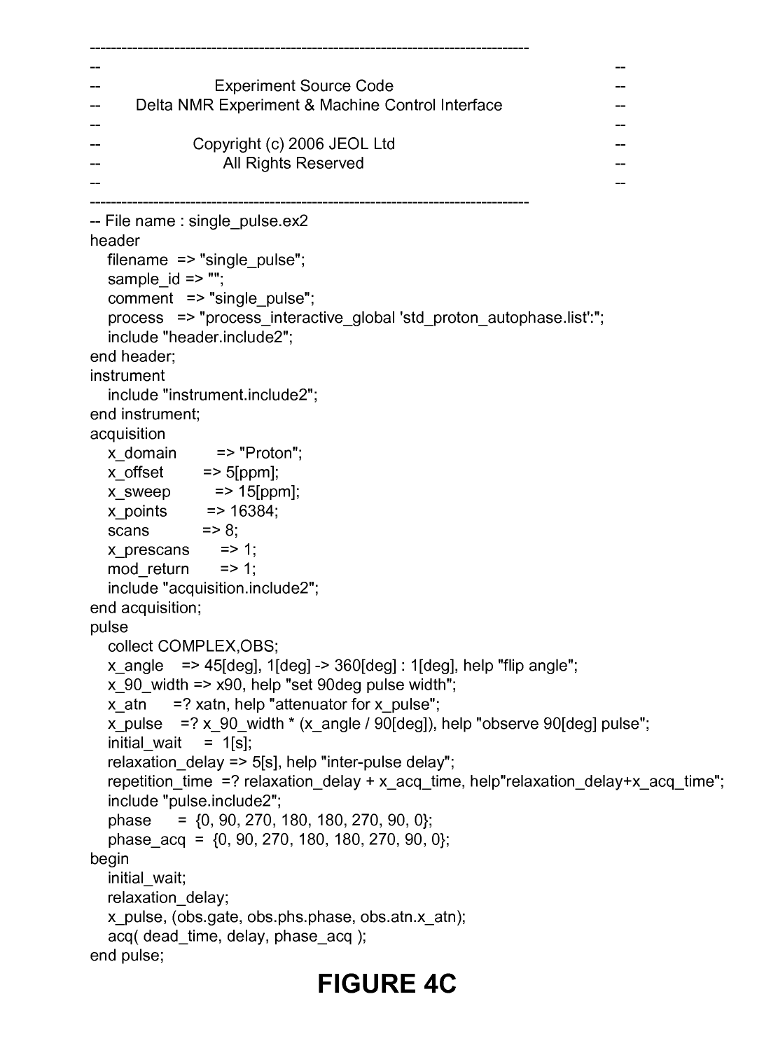

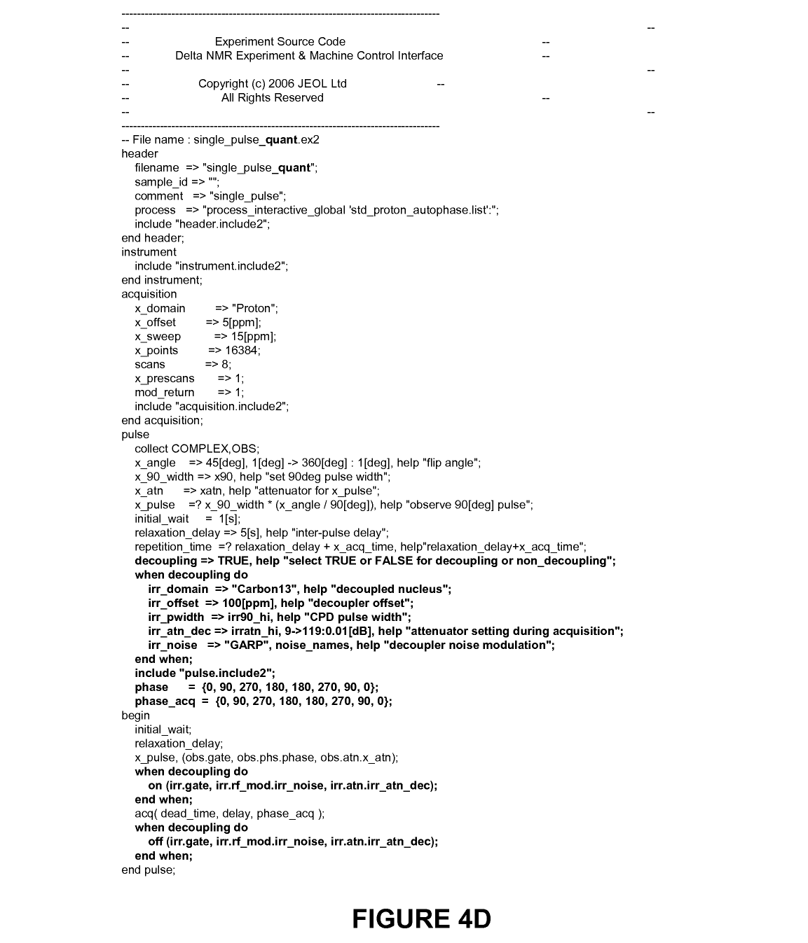

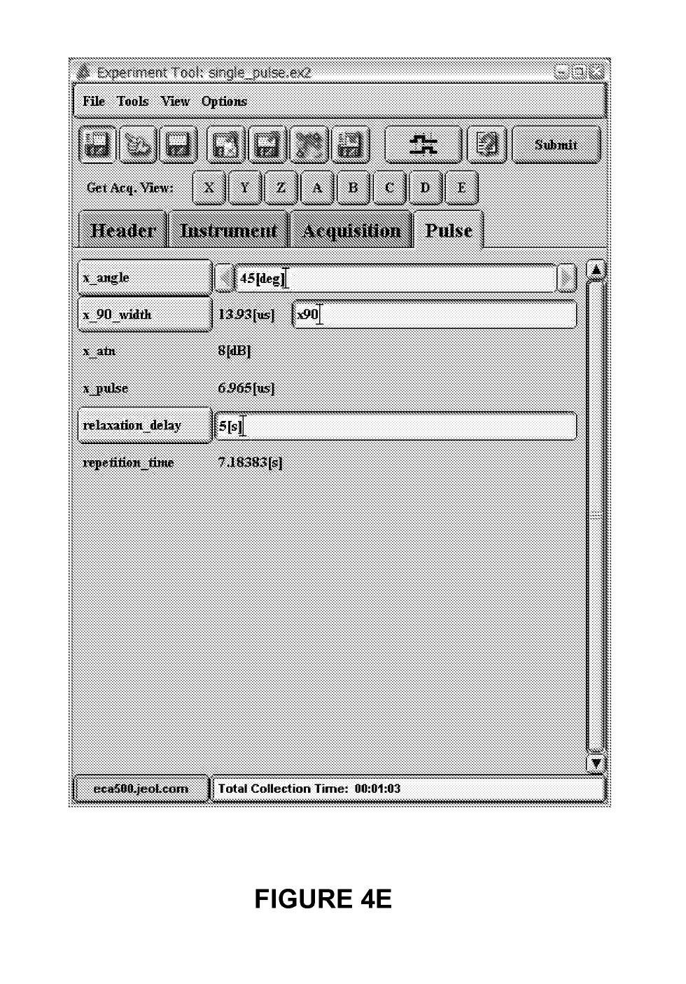

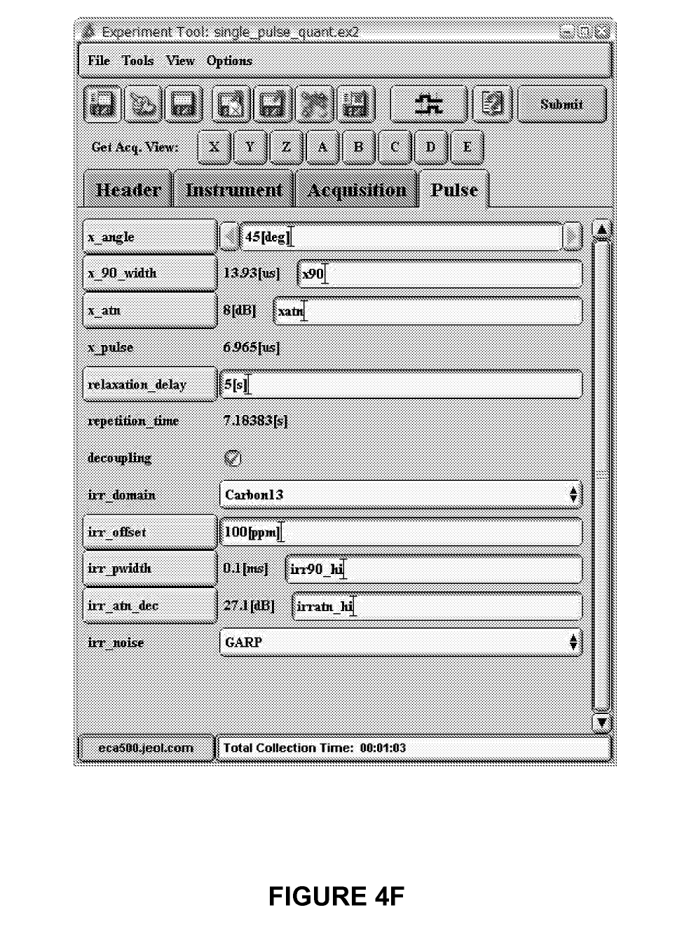

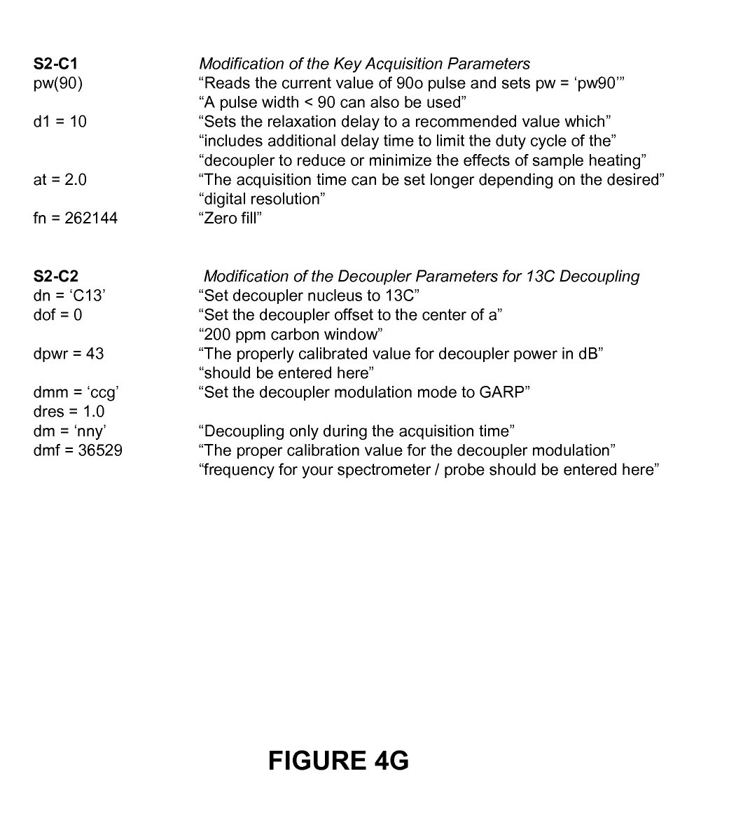

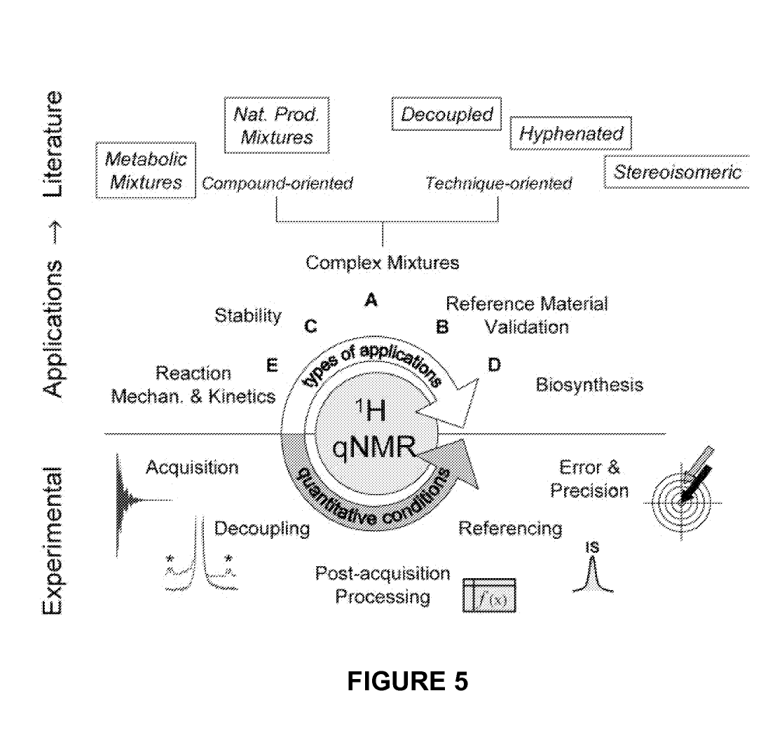

A Cookbook Approach to qHNMR: When it comes to practical aspects, qHNMR is a relatively uncomplicated 1D NMR experiment to implement, and relatively little additional effort is required to obtain the quantitative information through integral-based calculations as part of the routine post-acquisition processing of the spectra. There are, however, certain experimental details that need to be considered, and instrument parameters that require optimization in order for the methodology to be suitable for assessing the relatively complex spectra generated by natural products. In general, once the acquisition and processing parameters are established for any qHNMR experiment, either a parameter set or a set-up macro (e.g., see FIG. 4G) may be created on the NMR spectrometer, which can then be used to initiate and control the experiment in a much more routine manner and typically require little or no modification to the acquisition parameters (potential exceptions are the use of unusual solvents and/or relaxation behavior of the analyte). Two instrumental conditions distinguish the present qHNMR approach from a “normal” survey proton NMR experiment: (i) the qHNMR data are obtained non-spinning, and (ii) the qHNMR spectra are acquired with inverse gated ¹³C decoupling using a GARP (Globally-optimized Alternating-phase Rectangular Pulses)⁸ decoupling scheme. Additional key factors that are taken into account when establishing a routine qHNMR experimental protocol are discussed herein. These factors provide improved signal to noise and thereby improve sensitivity and applicability of the method to range of natural products. This includes a summary of key acquisition parameter settings, their effect on the qHNMR experiment, and some guidelines for their optimization. Summarized in the form of a “cookbook approach” to qHNMR (Table 2), the experimental setup is particularly useful as it is generally applicable to any natural product and independent of the NMR equipment manufacturer. Parameter information is provided for implementation on instruments from the major manufacturers (see FIG. 4 for summary of relevant graphical user interfaces, experimental source code, and macros for a number of commercial NMR systems), which serves as a set of guidelines for acquiring qHNMR data on virtually any contemporary pulsed FT-NMR spectrometer.

qHNMR Factor 1: Non-Spinning and Shimming of the Sample—The qHNMR experiment acquires data on a static sample; i.e., in non-spinning mode. This eliminates residual spinning sidebands, which represent artifacts that are frequently comparable in magnitude to low-level sample impurities and, thus, can be confusing. The presence of spinning sidebands can also lead to resonance distortion, due to signal overlap, and to errors in the accuracy of integrated intensities of the signals arising from both major component(s) of the sample as well as the minor impurities. Because of the excellent static magnetic field (Bₒ) homogeneity of the contemporary commercial superconducting magnets, most samples for NMR analysis can routinely be analyzed in a static non-spinning mode while maintaining the high resolution required for the detection of small coupling constants.

As required for all high-resolution NMR work, proper shimming of each sample to achieve good lineshape with good signal-to-noise (S/N) is clearly an important prerequisite. While both manual and automated shimming routines are options, gradient shimming capability will, in general, lead to the best lineshape in the shortest timeframe.

qHNMR Factor 2: Removal of ¹³C Satellites—In the protocol, qHNMR spectra are acquired with broadband decoupling of the ¹³C region to remove the ¹³C satellites from the ¹H spectrum. Therefore, a pulse sequence profile for the qHNMR experiment is assembled as illustrated in FIG. 1. Because the frequency range of ¹³C spectra is considerably larger compared to ¹H, relatively high power is required to achieve broadband decoupling, which in turn leads to sample heating. As a consequence, a composite-pulse decoupling scheme is employed for broadband decoupling, which applies efficient decoupling to the sample with minimum heat generation. One method used herein specifically employs the decoupling scheme known as GARP⁸ for the use in a qHNMR experiment, and allows coverage of the entire ¹³C shift range of protonated carbons, while minimizing sample heating and related effects (see also qHNMR Factor 3). GARP decoupling has the advantage over the Waltz-16 decoupling scheme, initially described as part of a qHNMR experiment,^{9,10} of decoupling over a broader ¹³C chemical shift range. However, Waltz-16 may still be employed if decoupling over a narrower ¹³C spectroscopic window (<100 ppm) is desired. Other composite pulse decoupling schemes such as WURST¹¹ or STUD,¹² which employ adiabatic pulses for decoupling, could be used as an alternative for further minimizing the heat produced during decoupling, especially for concentrated aqueous ionic samples.

qHNMR Factor 3: Relaxation Delay (d1)—The delay, in seconds, which precedes the pulsed qHNMR experiment is referred to as the relaxation delay, denoted on most commercial NMR spectrometers as d1. This delay is inserted to allow the excited nuclei to re-establish their equilibrium z-magnetization after the acquisition of the FID information and prior to the application of the next pulse or pulse train. If the pulse excitation is a 90-degree pulse, i.e., all equilibrium z-magnetization is converted into transverse (x,y) magnetization, the relaxation delay is generally set to 5 times the longest proton relaxation time (T₁) in the sample (determined by considering all proton resonances in the sample) in order to avoid distortion of integrated signal intensity due to relaxation effects. If the pulse excitation is a <90-degree pulse, then a shorter relaxation delay can in principle be employed. However, the relationship between the d1 delay, the proton relaxation times of the sample, and the “flip-angle” of the pulse used must also be considered. A further aspect of setting of the relaxation delay that requires comment relates to the application of composite pulse decoupling, in this instance ¹³C GARP decoupling, and the heat produced from the broadband decoupling during the acquisition time. While the length of the relaxation delay can be reduced, thus avoiding relaxation time effects and obtaining good quantitative results, decoupling of the carbon frequency range occurs during the acquisition time. Therefore, it is recommended to lengthen the relaxation delay to maintain a reasonable duty cycle (relaxation delay+acquisition time=pulse repetition rate) for the composite pulse decoupling and to minimize unfavorable heating effects. Minimizing heating effects serves to reduce excessive line broadening and, if the sample is heat sensitive, degradation of the sample during the course of the NMR data acquisition. In general, a duty cycle of 10-20% is recommended.

qHNMR Factor 4: Spectral Window Selection—The spectral window (syn. acquisition window or sweep width) is the region of radio frequency excitation that is used in a qHNMR experiment and, in part, depends on where the signals of interest reside. A wide qHNMR spectral window should be predetermined empirically, optimized for each solvent, and later can be adjusted to the specific conditions of a sample. Selection of an acquisition window for qHNMR should, however, always include a broader range, having additional region (˜2 ppm) added on to both the high field and low field ends of the desired spectral window of interest. This is recommended in order to compensate for the “roll off” (signal attenuation) of the analog filters (hardware) on the NMR spectrometer, which are used to restrict or eliminate aliasing (folding) of unwanted signals from outside of the desired spectral window. As a result, signal intensity appearing at the ends of the spectral window (out of the linear region of the analog filter) is severely attenuated (>70%) on either extreme end of the spectrum. This would lead to significant errors in the integrated intensities of the spectrum when attempting any kind of quantitative application. It is important to ensure that the spectral window of interest falls in the linear region of the analog filter. This will lead to both “flatter” baselines with good integrated intensities and elimination of signal attenuation at the edges of the spectrum. On most contemporary NMR spectrometers, the use of digital filtering (in contrast to analog filtering) and over-sampling generally provides improved baseline response, and the roll off problem tends to be reduced or eliminated. For a survey spectrum, a proton spectral window of 20 ppm is recommended as a general starting point. All contemporary NMR spectrometers are equipped with digital oversampling and digital filtering capabilities as an integral component of their hardware, so this aspect of the qHNMR acquisition is transparent to the spectroscopist. Oversampling improves the effective dynamic range (detection of small in the presence of large peaks), improves S/N, and leads to flatter baselines, all important factors for quantitation.

qHNMR Factor 5: Transmitter Position—Once the desired spectral window or sweep width is set in the spectrometer software, the transmitter offset frequency for excitation of the desired spectrum is positioned in the center of the spectral window. On most spectrometers the transmitter offset frequency is automatically adjusted depending on the spectral window selected. It can also be pre-defined as a solvent-dependent parameter value in a standardized qHNMR parameter set or be derived from an appropriate setup macro.

qHNMR Factor 6: Pulse Width Selection—The pulse width (pw) represents the length of the pulse excitation (in microseconds) that converts equilibrium magnetization (z) into transverse magnetization (x, y) at a specified transmitter power level. If all equilibrium magnetization is converted into transverse magnetization by the application of a radio frequency pulse, this is defined as a 90-degree pulse. Use of a 90-degree pulse results in creation of maximum signal intensity in the resultant spectrum. In order to acquire good quantitative NMR data in a reasonable period of time, however, a trade-off in the pulse width is employed. In practice, pulse widths of less than 90 degrees are often used. However, with prior knowledge of the value of the longest T₁ or ¹H relaxation time in the sample and a reasonable value for the relaxation delay, an optimum pulse width or flip angle (Ernst angle) can be determined¹³ and employed for qHNMR measurements.

qHNMR Factor 7: Selection of Acquisition Time—As noted earlier, following radio frequency excitation, creation and measurement of the free-induction decay (FID) represents the basic acquisition of a 1D NMR spectrum. The length of time that is spent to sample (or digitize) the FID is defined as the acquisition time. The acquisition time selected, in part, is related to the spectral window (see above) and to the desired level of digitization of the resultant NMR spectrum upon Fourier Transformation (FT), and should conform to the Nyquist relationship.^{14,15} In general, ample digitization (low Hz/point values; typically <0.2 Hz) is advantageous for quantitative work. Acquisition times of 2-4 sec @ 400 MHz are recommended.

qHNMR Factor 8: Selection of the Number of Scans or Transients—Selection of the number of scans (ns) or transients (nt) depends on the desired sensitivity, which in turn depends on the molecular weight and/or molar concentration of the analyte(s), and thus is sample dependent. Sensitivity is generally defined as the achieved signal to noise ratio (S/N) of the spectrum with respect to a particular signal in the sample, and increases as the square root of the number of scans or transients. For a qHNMR spectrum, sensitivity will not only depend on the amount of sample, but also on the complexity of or the level of impurities present in the sample. For the routine qHNMR provided herein, the better the S/N of the spectrum, and especially the better the S/N with respect to the lowest level component/impurity in the sample, the better the achievable quantitative accuracy. Thus, selection of the number of scans or transients for a qHNMR experiment is generally variable and sample dependent. However as a general guideline, acquisition of routine qHNMR spectra using a 400 MHz magnet and a 5 mm room temperature probe typically requires 256 transients for a 10 mg sample of a 500 amu compound (20 μmol).

qHNMR Factor 9: Receiver Gain Setting—The receiver gain (rg) is generally set automatically on most NMR spectrometers, but can be manually overridden, as it is an important parameter to set correctly. It is set prior to initiation of any data collection on the NMR spectrometer including qHNMR experiments. If the receiver gain is set too high, saturation of the receiver can result (“FID clipping”), and attenuation or in some cases signal elimination can result. In addition, severe baseline distortions may occur, which can have significant negative impact on the accuracy of quantitation. Setting the receiver gain too low can afford a spectrum with low S/N, requiring artificially high data collection times to achieve the desired S/N. Automated receiver gain optimization procedures are an integral feature on all modern NMR spectrometers.

qHNMR Factor 10: Steady State or “Dummy” Pulses—The use of steady state pulses, or “dummy” pulses, generally permits an equilibrium condition of any NMR experiment to be established prior to actually collecting and digitizing the FID information. All NMR spectrometers have this capability within their acquisition control software and, depending on the nature of the experiment, the number of steady-state pulses or dummy pulses used will be variable. The function of these pulses is simply to improve the reproducibility and to reduce variability of the data being collected. Once the experiment is in a “steady-state condition”, collection of the FID information will begin. Typically, 2-4 steady-state pulses are sufficient for a qHNMR experiment.

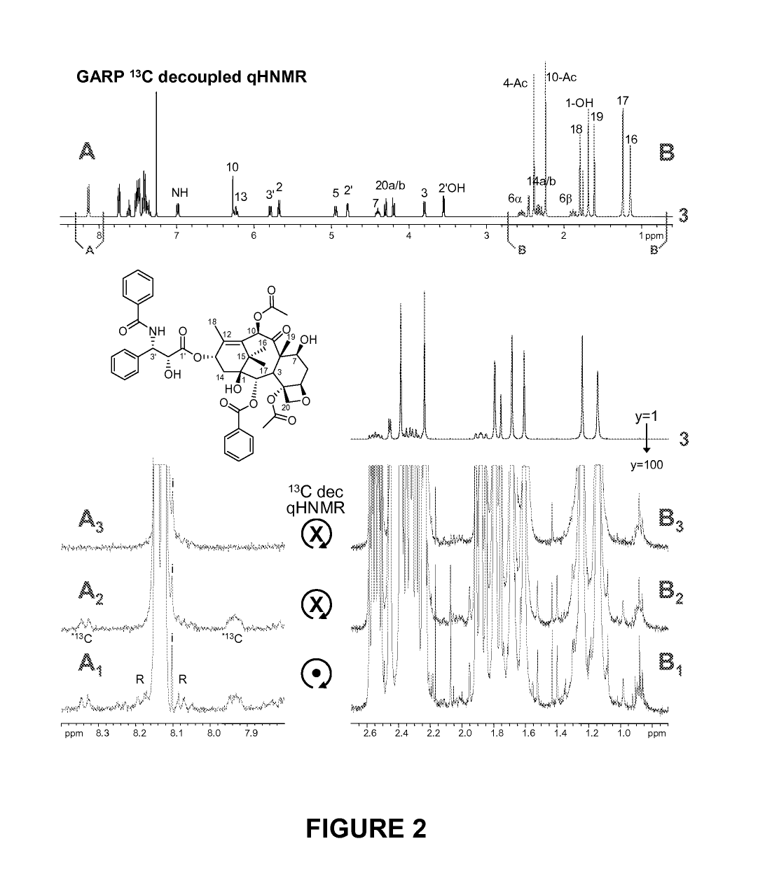

qHNMR Factor 11: ¹³C Decoupling—With further regard to the nature of the ¹³C decoupling noted above, the following two parameters need to be set correctly: the ¹³C spectral window, and the position of the ¹³C decoupler. The width of the ¹³C window to be decoupled can be limited to cover only the region concerned with protonated carbons, typically, δ0-180 ppm. However, to ensure that all protonated carbons are decoupled, and in order to standardize the acquisition parameter set, a spectral window of δ0-220 ppm may be recommended. In that fashion, aldehyde carbon resonances will, for example, be included in the decoupling process. The decoupler transmitter is then centered within the carbon window (δ110 ppm). The advantageous “baseline cleaning” (¹³C satellite removal) effect of, in this case, the ¹³C broadband GARP decoupling scheme on the acquired qHNMR spectra is illustrated for taxol in FIG. 2 (compare A3/B3 (non-spinning decoupled) against A2/B2 (non-spinning, no decoupling) and A1/B1 (spinning, no decoupling)).

### Example 2

### qHNMR Illustrated with Taxol

The qHNMR evaluation of taxol reference materials and related samples. In order to demonstrate the suitability of the proposed qHNMR method, taxol is used as a model analyte in the form of three different samples (Table 1): reference materials of varying purity of taxol (taxol A-C), a structurally related compound (taxoid D), and a crude extract of Taxus brevifolia bark. All five samples are subject to qHNMR analysis and their (im)purity profiles are quantitatively evaluated. Quantitative calculations are performed under the qualitative assumption that structurally related analogues, as evident from marker signals similar to those of taxol, are present as impurities.¹⁶ Due to the close structural similarities of the taxoids, the assumption is made that the molecular weight of the taxoid impurities is similar to taxol, and the identical mass (854 amu) is taken into account as a fictitious weight. This approach has empirically been proven to provide very reasonable quantitative results in purity analyses that are based on the 100% method^{5,17} (and from unpublished data using absolute quantitation; see also error discussion below). This assumption can be further verified with the methods disclosed herein because qHNMR provides impurity-related signals that contain structural information. Accordingly, the structure of the impurity can be verified as a structurally related analogue. In addition, the compound class of the impurity can be characterized, such as, for example, a fatty acid derivative, and from that classification an average mol weight is used in the calculation. In general, the more precisely the impurities are known, the more precise the absolute quantitative qHNMR-derived value.

Post-acquisition data processing is performed according to a spectroscopic processing concept that is specifically optimized for qHNMR spectra.¹⁸ Given the choice of acquisition conditions and parameters (GARP¹³C decoupled qHNMR sequence as in FIG. 1, acquisition parameters according to Table 2), the optimum choice of processing parameters is as follows. A Lorentzian-Gaussian resolution enhancement (LG) with a Gaussian factor of 0.05 (5% of AQ) and a line broadening factor of (−)0.3 Hz is used. The digital resolution of the 64 k-sized frequency domain spectra is maintained by adding an equal number of zeros (zero-filling) to the end of the original FID data, i.e., by single zero filling. Additional zero filling to 256 k data points is used to increase the overall digital resolution for the purpose of integration/quantitation. In order to improve the precision of the integration, further steps are taken for each individual qHNMR spectrum: (i) the baseline of the FID is corrected (DC correction); (ii) broad resonances such as those of water, other —OH and exchangeable protons, are eliminated by repeated line fitting and subtraction; and (iii) the overall baseline of the spectra is flattened by applying an n^{th} order polynomial correction (n<10).

For the reference materials, quantitation is based on the proportionality of the integrals of all detected resonances, and by assigning arbitrary values to presumably non-overlapped (“most pure”) reference resonances of the major taxoid in samples A-D, respectively (Table 1). Due to the conformational molecular dynamics of taxol, integration of the apparently non-overlapped signals at lower field still lead to slightly disproportionate integrals. Taking into account the underlying dynamic peak broadening/splitting, this deviation could be eliminated and almost the nominal integrals (value 100) be obtained by using relatively wide integration limits, which were necessary to cover the entire resonance signal. The proportionality is then calculated on the basis of all detected impurities, which are normalized to 100% of the total sample (“100% method” or “100%-minus-impurity approach”).^{5,17,19,20} Specifically, the signal groups of the H-10 and H-13 resonances, which appear in the range 6.18-6.27 ppm (sample taxol A and C), as well as the resonances assigned to H-5 and H-2′, appearing at 4.72-4.97 ppm for taxol B and taxoid D, are assigned integration values of 200 and, thus, served as internal reference signals with an arbitrary integral value of 100 per proton. The assignment of these two groups of non-overlapped reference signals is based on their maximum signal purity, as indicated by their minimum integral per proton compared to a the other resonances of the spectra. In order to aid in the assignment and detection of overlapping and non-overlapping impurity signals, 2D COSY spectra are employed.^{21,22}

Three of the four reference materials A-D are found to contain 2-4 different taxol analogues as the only impurities, while one of the samples contained a significant amount of aliphatic material (Table 1). The purities of the reference materials ranged from 84.7 to 94.7%. One of the samples (sample D), due to the blinded study, is initially analyzed as taxol, but turned out to be 10-deacetylbaccatin containing taxol as a minor impurity (1.44%). In general, the qHNMR based quantitative impurity profiles and sample purity values determined in this study are congruent with the liquid chromatography (LC)-based purity evaluation (Table 1). A noteworthy detail is that the qHNMR purities tend to be somewhat lower than LC-based values, which matches previously made observations. There are three obvious factors that could explain differences between NMR and chromatographic results. (i) NMR does not require calibration by a response factor, which is required in chromatographic quantifications, but often is unknown when doing chromatographic impurity profiling using the 100% method; also, chromatographic response factors can exhibit large differences. (ii) Chromatographic co-elution is more difficult to detect than NMR peak overlap: in chromatography only a single peak is obtained per analyte, whereas in NMR multiple signals arise from one analyte. (iii) Ubiquitously occurring natural “matrix substances” are likely to be omitted in chromatographic impurity profiling due to the lack of corresponding peaks (e.g., they may only give rise to an elevated baseline), whereas their detection in qHNMR will more likely occur as long as they contain protons. Systematic studies are needed comparing LC with qHNMR purity of natural products at different levels of purification in order to fully establish correlations between LC and qHNMR purities of natural products.

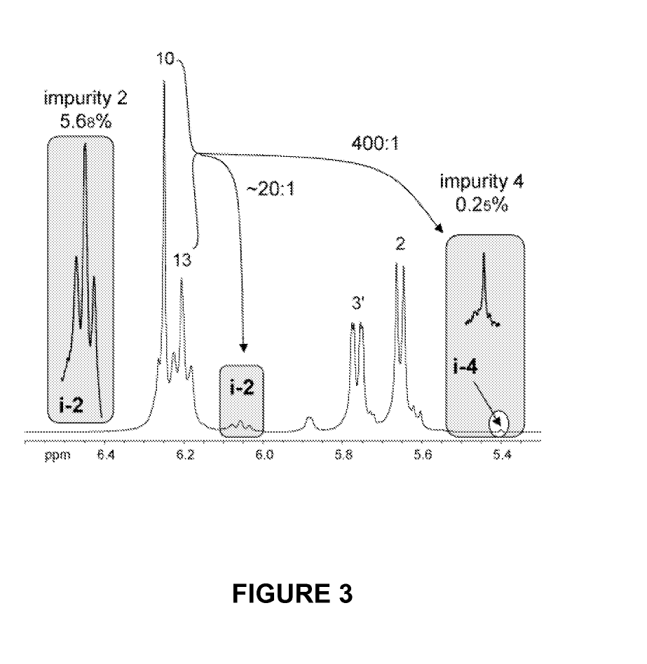

In one of the taxol samples (sample C) a minor impurity of an unassigned taxoid could be detected and was quantified to 0.25% using the qHNMR method disclosed herein. This demonstrates that routine qHNMR is capable of quantifying minor components in complex spectra with a dynamic range of 300:1 or better, as illustrated in FIG. 3. As this study is performed with blinded samples and structural information about the main analytes and the impurities is lacking, a systematic error related to the abovementioned molecular weight assumptions remains. In addition, the identity of all taxoid impurities in samples A-D is proved (data not shown). Those of ordinary skill in the art are capable of employing the technique disclosed herein to obtain qualitative (e.g., structural) along with the quantitative information of the impurities in a natural product mixture, including impurities that may not be of close structural relationship to the natural product of interest. Moreover, it is noteworthy that errors from molecular weight assumptions are diluted in proportion to the relative content of the minor component in the whole mixture. For example, even a 20% assumption error translates into a mere 0.2% deviation in the final 100% qHNMR mass balance.

### Example 3

### Metabolome Analysis

Application of the method to metabolome analysis is provided in a model system by the lower quantitation level of a structurally complex phytochemical contained in a chemically diverse mixture. Accordingly, a crude extract of Taxus brevifolia bark is analyzed by qHNMR as described, and taxol as a minor constituent in this crude metabolome mixture is determined to be present in the amount of 3.1(2) %. Due to severe signal overlap in this very complex T. brevifolia bark extract, additional processing of the qHNMR spectrum is necessary. The only signal that is sufficiently isolated and amenable for quantitation is the signal of H-10 at 6.250 ppm. Prior to integration, interfering signals resulting from the numerous other components contained in the extract, which are convoluted to an underlying hump, are line-fitted and subtracted from the spectrum. In addition, it is evident from the analysis of the taxol reference materials A-C that the integral for H-10 had to be set to an arbitrary value of 125 instead of 100, since the H-10 resonance demonstrated overlap (25% by integral) with the resonance of H-13. The final calculation of the taxol content in the extract is based on the relative integrals in the region between 7.29 and 8.20 ppm as follows. In pure taxol, the signal of 15 protons resonates in this chemical shift range. Therefore, their arbitrary integral value is set to 1500 for “pure” taxol, and is subsequently related to the measured total integral (48144) of the signals of the extract sample resonating in the same chemical shift range. This led to the calculation of a content of 3.1(2) % of taxol in the investigated T. brevifolia bark extract (see FIG. 3), which correlates reasonably well with a value of 4.0% as determined by HPLC, taking into account the likelihood of both chromatographic peak and NMR signal overlap. This observed congruence generally validates the role of qHNMR in metabolomic analyses.

### Example 4

### Routine qHNMR of Natural Products and Biological Reference Materials

The results of this study illustrate the feasibility and robustness of routine GARP¹³C-decoupled qHNMR analysis of relatively complex molecules and mixtures thereof. The qHNMR concept is robust in that it provides sensitive and reliable information even when working with deliberately flawed assumptions regarding, e.g., when exact structures and MW of impurities are unavailable (see above); when using imperfect molar masses in calculations that apply the 100% normalization/mass balance method; and when dealing with relatively demanding analytes such as taxol that exhibit a highly complex ¹H resonance pattern that are complicated by the presence of various conformers at RT. Accordingly, the qHNMR methods provided herein are amenable for use in a wide range of applications and for a wide range of natural products.

The key advantages of qHNMR besides being a relatively inexpensive and fast method include: (i) qHNMR can reliably distinguish “highly pure” from “less pure” reference material with precisions in the range of 0.1%; (ii) qHNMR allows detection of even very low proportions of a target analyte (e.g., 3.1% of taxol in T. brevifolia extract) or impurities (<1%) in complex matrices by detailed targeted processing of single signals, e.g., in crude extract and metabolome analysis; (iii) the qHNMR concept comes included with a tool for the verification of the authenticity of the (target) analyte through the direct structural evidence contained in individual ¹H resonances (marker signals); (iv) qHNMR has the potential to become a routine technique of almost universal applicability, even in research environments with entry-level instrumentation (300-400 MHz) and/or when using relatively small amounts (<10 mg) of high molecular weight samples (taxol: 854 Daltons).

Because of the potential biological implication of the various constituents and impurities that in a given sample can be present at widely varying abundances (˜10 to 0.1%), the qHNMR methods and systems presented herein provide a value-added dimension to the standard set of spectroscopic data. Consequently, it is reasonable to incorporate qHNMR assays, methods, and spectra thereof, as part of a routine structure elucidation process and/or quality control for natural products, particularly new natural products having biologic activity. Because the qHNMR method realistically requires almost no additional effort (e.g., no additional equipment), except for the task of establishing the quantitative conditions for the standard ¹H NMR experiments provided herein, it is readily integrated into the workflow of any routine qualitative NMR protocol. Considering that qHNMR readily covers a dynamic range of 300:1 or better, its suitability for quantitative metabolome analysis is evident. At the same time, the method is capable of positive identification of metabolites through marker signals, which add to the portfolio of qHNMR in metabolome and natural products research.

NMR Spectroscopy. The ¹H NMR data (400 MHz) described herein is obtained on either a Bruker DPX-400 NMR spectrometer using a 5-mm QNP probe or a Bruker AVANCE-400 NMR spectrometer using a 5-mm broadband ATM probe. The taxol samples (about 10 mg) are weighed to precision, dissolved in CDCl_{3 (Aldrich Chemical/Isotech), and then transferred, with filtering through a “plug” of cotton wool, into a} 5-mm NMR tube with a total volume of solution of ˜700 uL. A standard ¹H NMR experiment (without ¹³C decoupling) is quickly obtained to evaluate the sample shimming. A ¹³C GARP decoupled qHNMR spectrum is then obtained using the pulse profile described in FIG. 1 and in Table 2. The latter also provides parameter sets that encode the acquisition conditions for modern spectrometers from all major NMR instrument manufacturers (Bruker, Jeol, and Varian).

Qualitative NMR of taxol. The NMR data of taxol shown here generally refer to assignments that are well documented,^{16,23-26} and the observed spectra (FIG. 2) are qualitatively identical with the published data.

### Example 5

### Quality Control and qHNMR

The qHNMR methods provided herein have a specific application in the analysis of substantially pure materials. For example, commercially available reference materials are generally provided with a certificate of analysis providing quantitative information regarding reference material purity. Generally, such purity is obtained by a conventional method such as chromatography where as discussed, there are concerns about the method's ability to provide an accurate quantitative determination. For example, chromatography depends on selective detection, which is prone to failure and often yields erroneous results. In contrast, the qHNMR methods provided herein is universal (e.g., presence of protons), less prone to failure and can be extremely sensitive and reliable. As an example, TABLE 3 summarizes the results obtained for four commercially available reference materials (labeled sample A-D) containing ursolic acid. The certificate of analysis provided with the material states the purity of the material as determined by chromatography. The “determined qHNMR purity” column is the purity determined by the qHNMR method provided herein, indicating that two of the commercial reference materials are of significantly lower purity than indicated by the manufacturer. Two of the samples are not significantly different. Accordingly, there is a potential lack of correlation between chromatographic and qHNMR purity, indicating chromatographic methods suffer limitations. Many other commercially available reference materials suffer similar deficiencies (e.g., see alpha-Onocerin and hyperforin in TABLE 3), providing further indication of the general applicability of the claimed qHNMR methods to a wide range of materials and natural products. Of course, other reference materials are confirmed via qHNMR of the present invention to match the advertised purity levels. There is, however, no reliable method for determining whether a sample meets the chromatographically-determined purity level a priori. Accordingly, the methods provided herein are a valuable tool for a number of parties, such as manufacturers of such reference materials and users of those materials, as part of their quality control process.

### Example 6

### Low Level Detection by qHNMR

qHNMR is capable of providing low level detection of materials, such as for low-molecular weight target analytes including, but not limited to, residual solvents in a high qNMR purity natural product reference material (see TABLE 4). For example, TABLE 4 demonstrates that qHNMR is capable of determining the present of water. Chromatographic analysis, in contrast, cannot account for the present of water. The analysis of the natural product, hyperforin, indicates that qHNMR is capable of reliably measuring a material (in this case methanol) at a lower detection limit that is 0.01% or better.

qHNMR protocols with various commercial NMR spectrometers. FIG. 4 summarizes Respective Vendor Implementation of the Acquisition of Routine GARP ¹³C-Decoupled qHNMR Spectra (Vendors in Alphabetical Order). FIG. 4A is Routine GARP¹³C-Decoupled Quantitative Proton NMR (qHNMR) on Bruker NMR Spectrometers. By typing ‘edasp’, a display similar to that shown in FIG. 4A will appear. The nucleus and frequency information must be modified by the user to permit ¹³C decoupling during the acquisition. The routing panel should look like the panel shown in FIG. 4A.

FIG. 4B is the standard pulse sequence code ‘zgig30’ for inverse decoupling (decoupling during acquisition) using a 30° excitation pulse. It is available on instruments purchased from Bruker-Biospin. The standard sequence ‘zgig’, where a 90° pulse is employed, may also be used. Both may be used without modification and a parameter set using either sequence may be created by the user called ‘qHNMR30_GARP_C’ and ‘qHNMR90_GARP_C’ using these pulse sequences, respectively.

FIGS. 4C-D show experimental source code for Routine GARP¹³C-Decoupled Quantitative Proton NMR (qHNMR) on JEOL NMR Spectrometers (C is a Standard 1-D Single Pulse Experiment; D is Standard 1-D Single Pulse Experiment with GARP Decoupling During the Acquisition). The differences from the code in FIG. 4D from FIG. 4C are bolded and are required for implementation of GARP decoupling during acquisition.

FIG. 4E is a Screen Shot of the Standard 1-D Proton NMR Experiment. FIG. 4F is a Screen Shot of 1-D qHNMR Experiment Parameter Setup with Decoupling Checked and GARP Applied.

FIG. 4G is Routine GARP¹³C-Decoupled Quantitative Proton NMR (qHNMR) on Varian NMR Spectrometers, and more specifically a macro, ‘qhnmr’, that is executed to modify a standard proton observe parameter set, which uses the ‘s2pul’ pulse sequence, for quantitative proton NMR with carbon decoupling during the acquisition. Carbon decoupling will suppress the signals arising from the carbon-13 satellites. Adjustment of the receiver gain on each sample should be performed prior to initiating data acquisition. The modification or addition of other parameters may be included in the setup macro at the user's discretion.

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

Every formulation or combination of components described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.
(1) Newman, D. J.; Cragg, G. M.; Snader, K. M. J. Nat. Prod. 2003, 66, 1022.
(2) Newman, D. J.; Cragg, G. M.; Snader, K. M. Nat. Prod. Rep. 2000, 17, 215.
(3) Cragg, G. M.; Newman, D. J.; Snader, K. M. J. Nat. Prod. 1997, 60, 52.
(4) Eldridge, G. R.; Vervoort, H. C.; Lee, C. M.; Cremin, P. A.; Williams, C. T.; Hart, S. M.; Goering, M. G.; O'Neil-Johnson, M.; Zeng, L. Anal. Chem. 2002, 74, 3963.
(5) Pauli, G. F.; Jaki, B.; Lankin, D. J. Nat. Prod. 2005, 68, 133.
(6) Pauli, G. F.; Jaki, B.; Lankin, D.; Walter, J. A.; Burton, I. Quantitative NMR of Bioactive Natural Products in Bioactive Natural Products; 2nd ed.; Colegate, S, and Molyneux, R., Ed.; Taylor & Francis: New York, 2007, in press.
(7) Szantay, C.; Beni, Z.; Balogh, G.; Gati, T. TrAC, Trends in Analytical Chemistry 2006, 25, 806.
(8) Shaka, A. J.; Barker, P. B.; Freeman, R. J. Magn. Reson. 1985, 64, 547.
(9) Simeral, L. S. Today's Chemist at Work 1993, 11, 52.
(10) Simeral, L. S. Appl. Spectrosc. 1995, 49, 400.
(11) Kupce, E.; Freeman, R. J. Magn. Res., Series A 1995, 115, 273.
(12) Bendall, M. R.; Skinner, T. E. J. Magn. Reson. 1998, 134, 331.
(13) Ernst, R. R.; Anderson, W. A. Rev. Sci. Instru. 1966, 37, 93.
(14) Claridge, T. D. W. High-resolution NMR Techniques in Organic Chemistry; Pergamon: New York, 1999.
(15) Derome, A. E. Modern NMR Techniques for Chemistry Research; Pergamon Press: New York, 1987.
(16) Chmurny, G. N.; Paukstelis, J. V.; Alvarado, A. B.; McGuire, M. T.; Snader, K. M.; Muschik, G. M.; Hilton, B. D. Phytochemistry 1993, 34, 477.
(17) Pauli, G. F. Phytochem. Anal. 2001, 12, 28.
(18) Jaki, B.; Chadwick, L.; Chen, S.-N.; Pauli, G. F. The Pivotal Role of Spectral Processing in the Quantitative ¹H NMR Analysis of Natural Products; Annual Meeting of the American Society of Pharmacognosy: Corvallis (OR), 2005, July 23-27 (#O34).
(19) Pinciroli, V.; Biancardi, R.; Visentin, G.; Rizzo, V. Org. Proc. Res. Devel. 2004, 8, 381.
(20) Rizzo, V.; Pinciroli, V. J. Pharm. Biomed. Anal. 2005, 38, 851.
(21) Malz, F. Quantitative NMR-Spektroskopie als Referenzverfahren in der Analytischen Chemie; Ph.D. Dissertation, Humboldt-Universität Berlin: Berlin, 2003, 147 pp.
(22) Malz, F.; Jancke, H. J. Pharm. Biomed. Anal. 2005, 38, 813.
(23) Hilton, B. D.; Chmurny, G. N.; Muschik, G. M. J. Nat. Prod. 1992, 55, 1157.
(24) Chmurny, G. N.; Hilton, B. D.; Brobst, S.; Look, S. A.; Witherup, K. M.; Beutler, J. A. J. Nat. Prod. 1992, 55, 414.
(25) Barboni, L.; Lambertucci, C.; Appendino, G.; Vander Velde, D. G.; Nimes, R. H.; Bombardelli, E.; Wang, M.; Snyder, J. P. J. Med. Chem. 2001, 44, 1576.
(26) Snyder, J. P.; Nevins, N.; Cicero, D. O.; Jansen, J. J. Am. Chem. Soc. 2000, 122, 724.

Jaki, Sticher, Veit, Fröhlich, Pauli, J. Nat. Prod. 2002, 65, 517-22

TABLE 1
Quantitative impurity profiles of three reference materials (taxol A-C,
taxoid D) and a crude T. brevifolia extract^{a} investigated by qHNMR.

| | Number | | | | |
|---|---|---|---|---|---|
| | of | Impurity | Taxol purity or | Nature of | LC-based |
| Sample | impurities | in % | content in % | impurity | content in % |
| Reference | | | | | |
| Materials | | | | | |
| taxol A | imp1 | 4.6(9) | 89.8(7) (w aliph. | taxoid | n.a. |
| | imp2 | 5.1(3) | material) | taxoid | |
| | imp3 | 0.3(1) | 94.7(3) (w/o aliph. | aliphatic | 96.9 |
| | | | material) | material | |
| taxol B | imp1 | 8.3(7) | 84.7(3) | taxoid | n.a. |
| | imp2 | 5.6(8) | | taxoid | |
| | imp3 | 0.9(1) | | taxoid | |
| | imp4 | 0.2(5) | | taxoid | |
| taxol C | imp1 | 4.9(2) | 85.5(7) | taxoid | 85.6 |
| | imp2 | 9.5(1) | | taxoid | |
| taxoid D^{b} | — | — | 1.4(4) | taxol | |
| | % taxol | | | | |
| Crude Extract | content | | | | |
| T. brevifolia | 3.1 | | | | 4.0 |
| bark extract^{a} | | | | | |

^{a}The taxol content of the extract was determined as 4.0% by HPLC
^{b}10-Deacetylbaccatin

TABLE 2^{c}
A Cookbook Approach^{a} to qHNMR Providing General Guidelines for the
Choice of NMR Acquisition and Processing Parameters

| parameter | suggested value | comments |
|---|---|---|
| Acquisition Parameters | | |
| acquisition time (aq or at) | 2-4 s | Will vary with sample/spectral window; sele [symbol] |
| | | short value for inverse-gated decoupled qH [symbol] |
| | | to reduce heating effects. |
| relaxation delay (d1) | 10 s | Should reflect 5 times the longest T₁ in the |
| | | sample for 90° pulses; longer delays are |
| | | maintained to reduce the duty cycle of the |
| | | decoupler in inverse-decoupled qHNMR |
| pulse width (pw or p1) | 15°-45° | Ideally, use Ernst angle calculated for |
| | | each sample (function of the longest T₁ in |
| | | the sample) |
| time domain | 64k | Should be zero-filled to at least 256k |
| | | points, but not linear predicted |
| spectral width (sw) | sample spectral | Depends on the type of electronic filtering |
| | window ± 3 ppm on | used (analog/digital) and |
| | each end | should be pre-determined for the general |
| | | use case and stored in the qHNMR |
| | | parameter set. |
| transmitter offset | center of the ¹H | Automatically set by spectrometer |
| | spectral width | |
| receiver gain | closely below the | Automatically set by spectrometer but |
| | highest possible | large values should be avoided. |
| | setting | |
| number of scans/transients | 128-1024 | Dependant on molar concentration of the |
| | | sample, desired S/N, magnetic field |
| | | strength, and level of desired quantitative |
| | | accuracy required |
| Processing Parameters | | |
| window function | lb = 0.1-0.3 | Minimum exponential multiplication, |
| | | alternative window functions may be |
| | | considered, e.g., Gaussian multiplication |
| | | with lb −0.3 and gb 0.05, or TRAF[S] |
| phasing | manual | Still the best way to do it |
| baseline correction | n^{th} order polynomial | Manually optimized |

^{a}Updated version of Table 1 from Pauli, G. F.; Jaki, B.; Lankin, D. J. Nat. Prod. 2005, 68, 133-149.
^{b}Typical requirement: ≧256 sans @ 400 MHz w/5 mm probe for 10 mg of a 500 amu cpd.
^{c}Note, these parameters are not limiting, but are guidelines for a user implementing qHNMR. [symbol]
indicates data missing or illegible when filed

TABLE 3
Comparison of chromatographic and qHNMR purity analysis

| | declared | determined | |
|---|---|---|---|
| | chromatographic | qHNMR | |
| Sample | purity | purity | difference |
| Ursolic acid sample A | 81.00% | 69.66% | 11.34% |
| Ursolic acid sample B | 99.57% | 87.67% | 11.90% |
| Ursolic acid sample C | 98.6% | 98.64% | |
| Ursolic acid sample D | 98.6% | 97.48% | |
| alpha-Onocerin | “>98%” | 86.7% | >11.3% |
| hyperforin | “>98%” | 95.1% | >2.9 |

TABLE 4
Detection of low-level low-molecular weight target analytes

| | determined | declared | | declared | |
|---|---|---|---|---|---|
| | qHNMR | residual | residual | residual | residual |
| Sample | purity | ethanol | methanol | water | water |
| Glucoiberin | 97.65% | 0.065% | 0.216% | | |
| Hyperforin | 95.1% | n.d. | 0.010% | 0% | 8.7% |

1. A method for qualitative and quantitative determination of a natural product by proton nuclear magnetic resonance, said method comprising:
a. providing a sample containing said natural product;
b. introducing said sample into a measuring cell of a nuclear magnetic resonance analysis apparatus;
c. decoupling of ¹³C nuclei in said sample by a composite pulse decoupling scheme; and
d. obtaining a spectrum thereof, wherein said decoupling ¹³C nuclei in said sample removes ¹³C satellites from said spectrum thereby providing the capability of quantitative and qualitative determination of said natural product;
wherein, said spectrum has peaks providing qualitative characterization of a species structure in said sample, and said peak has a shape parameter capable of providing quantitative determination of an amount of said species associated with said peak in said sample.

2. The method of claim 1, wherein said decoupling is provided by a composite pulse decoupling scheme selected from the group consisting of:
a. globally optimized alternating-phase rectangular pulses (GARP);
b. WURST;
c. WALTZ-16; and
d. STUD.

3. The method of claim 2, wherein said decoupling is provided by GARP.

4. The method of claim 2, wherein said spectrum is obtained from a non-spinning sample.

5. The method of claim 1, wherein said quantitative determination of said shape parameter is by measuring an area or a maximum height corresponding to a region constrained by said peak.

6. The method of claim 1, wherein the sample is selected from the group consisting of
a. a reference material;
b. a biologically active material or precursor thereof;
c. a mixture of one or more known natural products; and
d. a mixture of one or more unknown natural products.

7. The method of claim 6, wherein said sample is a reference material and said method further comprises:
a. analyzing said sample for one or more impurities.

8. The method of claim 7, wherein said reference material is a commercially-available reference material for use in calibrating an analytical instrument.

9. The method of claim 8, further comprising the step of:
a. quantifying an impurity level, if present; and
b. rejecting said reference material if said level of impurity exceeds a selected impurity level.

10. The method of claim 7, wherein the reference material is selected from the group consisting of:
a. a botanical material;
b. a material derived from a micro-organism;
c. a natural product of a compound class derived from a biosynthetic pathway, said compound class is one or more of phenylpropanoids, terpenes, sugar, sugar derivative, acetogens, amino acid derivatives or alkaloids;
d. a biologically active material; and
e. a mixture thereof.

11. The method of claim 1, wherein the sample comprises a natural product that is a high-purity material, a medium purity material, or a crude extract.

12. The method of claim 11, wherein the sample comprises a high-purity natural product material.

13. The method of claim 11, wherein the sample is a crude extract, wherein said crude extract comprises a mixture of natural products.

14. The method of claim 1 wherein the quantitative and qualitative determination is from the same spectrum.

15. The method of claim 14, wherein the method is non-destructive.

16. The method of claim 1, further comprising adjusting one or more nuclear magnetic resonance acquisition parameters to improve sensitivity or selectivity, wherein the parameter is selected from the group consisting of one or more of:
a. spinning or non-spinning sample;
b. shimming;
c. composite-pulse decoupling scheme for broadband decoupling with minimum heat generation;
d. pulse delay time;
e. angle of pulse excitation;
f. a spectral window, wherein a transmitter offset frequency for excitation of the desired spectrum is positioned in the center of the said spectral window;
g. pulse width;
h. acquisition times of between about 2 to 4 sec at about 400 MHz
i. number of scans or transients
j. receiver gain setting
k. number of steady-state pulses; and
l. ¹³C spectral window and a position of the ¹³C decoupler relative the ¹³C spectral window.

17. The method of claim 1, wherein said obtaining a spectrum step further comprises providing solvent suppression to provide an improved spectrum having a dynamic range that is increased compared to a spectrum that is not solvent suppressed.

18. The method of claim 17, wherein said solvent suppression is by transmitter presaturation or gradient solvent suppression.

19. A method for detecting the presence or absence of an impurity in a sample by quantitative proton nuclear magnetic resonance spectroscopy, said method comprising:
a. providing said sample, wherein said sample has a reference material;
b. introducing said sample into a measuring cell of a nuclear magnetic resonance analysis apparatus;
c. decoupling of ¹³C nuclei in said sample; and
d. obtaining a spectrum thereof, wherein said decoupling ¹³C nuclei in said sample removes ¹³C satellites from said spectrum thereby providing the capability of quantitative and qualitative determination of said reference material and the capability of quantitative and qualitative determination of said impurity, if present.

20. The method of claim 19, further comprising characterizing said impurity structure.

21. The method of claim 19, further comprising determining the amount of impurity in said sample.

22. The method of claim 19, wherein the ¹³C decoupling is provided by a GARP scheme.

23. The method of claim 19, wherein the reference material is a natural product.

24. The method of claim 23, wherein the natural product is an active pharmaceutical ingredient.

25. The method of claim 23, wherein the reference material has a structure that is not known prior to performing said method.

26. A method for analyzing a complex mixture by proton nuclear magnetic spectroscopy, said method comprising:
a. providing said complex mixture, wherein said mixture comprises a plurality of natural products;
b. introducing said sample into a measuring cell of a nuclear magnetic resonance analysis apparatus;
c. decoupling of ¹³C nuclei in said sample; and
d. obtaining a spectrum thereof, wherein said decoupling ¹³C nuclei in said sample removes ¹³C satellites from said spectrum thereby providing the capability of quantitative and qualitative determination of said complex mixture;
wherein said spectrum provides quantitative and qualitative characterization of each of said plurality of natural products.

27. The method of claim 26, wherein said complex mixture further comprises a target analyte, wherein said quantitative and qualitative characterization provides a quality control parameter for said target analyte.

28. The method of claim 27, wherein said quality control parameter is selected from the group consisting of:
a. concentration of said target analyte in said sample;
b. presence or absence of impurities.
c. biological activity;
d. relative amount of said natural product to said target analyte; and
e. amount of said natural product and said target analyte.

29. The method of claim 1, wherein said natural product or impurity that is quantitatively determined is present at a level that is about 1% or less.
